(19) United States
(12) Patent Application Publication
(10) Pub. No.: US 2002/0033486 A1
(43) Pub. Date: Mar. 21, 2002

(54) Method for forming an interconnection line using a hydrosilsesquioxane (HSQ) layer as an interlayer insulating layer

(75) Inventors: Won-Jin Kim, Kyunggi-do (KR); Soo-Geun Lee, Kyunggi-do (KR); Hong-Jae Shin, Seoul (KR); Jae-Hyun Han, Seoul (KR); Jae-Hak Kim, Seoul (KR); Ho-Kyu Kang, Kyunggi-do (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-city (KR)

(21) Appl. No.: 09/919,628

(22) Filed: Jul. 30, 2001

(30) Foreign Application Priority Data
Aug. 4, 2000 (KR) 2000-45279
Nov. 27, 2000 (KR) 2000-70973

(51) Int. Cl. H01L 29/74; H01L 31/111

(52) U.S. Cl. 257/118

(57) ABSTRACT

Disclosed is a method for forming interconnection lines using a hydrosilsesquioxane (HSQ) layer as an interlayer insulating layer. A HSQ layer is formed over a semiconductor substrate and an entire surface of the HSQ layer is subjected to plasma treatment. It is then possible to pattern the HSQ layer using photo etching, for the bond structure density of an upper part of the HSQ layer has been increased due to the plasma treatment. An opening is formed by patterning the treated HSQ layer and then a conductive layer filling the opening is formed. In this manner, a multilayer interconnection structure can be formed with a low dielectric layer made of HSQ, thereby reducing the resistance-capacitance (RC) delay.

This application relies for priority upon Korean Patent Application No. 2000-45279, filed on Aug. 4, 2000 and Korean Patent Application No. 2000-70973, filed on Nov. 27, 2000, the contents of which are herein incorporated by reference in their entirety.

### BACKGROUND OF THE INVENTION

As the density of semiconductor elements increases, the sectional areas and intervals of the multilayer metal interconnection line connecting the unit elements decrease. This causes the resistance of the metal interconnection line and the parasitic capacitance between the lines to increase, which results in a resistance-capacitance (RC) delay. Thus, characteristics of the semiconductor elements are degraded.

To improve these problems, there have been attempts to employ copper (Cu) as a conductive material for the metal interconnection line. Cu has not only a lower specific resistance relative to the conventional materials such as aluminum (Al) or tungsten (W), but also excellent resistance characteristics against electro-migration. Additionally, a method for reducing the parasitic capacitance is to employ a dielectric layer having a lower dielectric constant than that of the conventional silicon oxide layer. In particular, an interlayer insulating layer made of hydrosilsesquioxane (HSQ), which has a dielectric constant of 3.0, is drawing attention in the technology.

The Cu interconnection line is formed using a damascene process. The damascene process includes the steps of forming an opening by patterning the insulating layer, filling the opening with the conductive material, and then etching the layer for planarization. When the interlayer insulating layer is made of HSQ, a photolithography process can not be applied to pattern the HSQ layer.

Specifically, the HSQ layer may crack when it is exposed to developer after a predetermined region of a photoresist layer coating the HSQ is selectively exposed. Therefore, when the HSQ layer is employed as the interlayer insulating layer, the patterning is performed by a dry etch after forming a hard mask on the HSQ layer. For example, a photoresist pattern is coated on a silicon oxide layer which is formed on the HSQ layer, and then the silicon oxide layer and the HSQ layer are sequentially subjected to the dry etch process for patterning the HSQ layer.

However, when the silicon oxide layer is formed on the HSQ layer, the etch process of the silicon oxide layer and the HSQ layer causes a bowing phenomenon on the sidewalls of patterned openings due to etch rate variation. In other words, if the silicon oxide layer and the HSQ layer are synchronously etched, the HSQ layer with the higher etch rate is etched more than the silicon oxide layer, so that the sidewalls of the lower portion of the opening are concave. Such a bowing phenomenon causes a void in the lower portion of the opening during a subsequent process that fills the opening with the conductive layer. In addition to this problem, a residual silicon oxide layer on the HSQ layer increases the effective dielectric constant of the interlayer insulating layer.

Recently, a method using a titanium nitride (TiN) layer as the hard mask in patterning the HSQ layer was introduced. The method is disclosed in the paper by Aoki et al. entitled “A Degradation-Free Cu/HSQ Damascene Technology using Metal Mask Patterning and Post-CMP Cleaning by Electrolytic Ionized Water”, published by International Electron Devices Meeting (IEDM) 1997, p.777. According to the paper, the silicon oxide layer is patterned by the photolithography process after sequentially forming the TiN layer and the silicon oxide layer on the HSQ layer. A TiN pattern is formed by etching the TiN layer using the silicon oxide layer pattern as an etch mask. The TiN pattern is used as a hard mask in a subsequent process. Thereafter, the HSQ layer is etched to form the opening using the TiN pattern as the etch mask.

The bowing phenomenon described above is cured by Aoki's process, since the HSQ layer is etched after the TiN pattern is formed. Furthermore, the TiN pattern remaining on the HSQ layer is removed when the conductive material is etched for planarization, so the effective dielectric constant of the interlayer insulating layer does not increase. However, the process requires complex processing steps, and productivity is degraded.

### SUMMARY OF THE INVENTION

The present invention relates generally to a method for fabricating semiconductor devices. In particular, it is an object of the present invention to provide a method for forming an interconnection line using the hydrosilsesquioxane (HSQ) layer of a low dielectric constant material as an interlayer insulating layer to reduce parasitic capacitance.

One embodiment of the present invention provides a method for forming an interconnection line. The method begins by forming a low dielectric layer over a semiconductor substrate. “Over” as used herein can mean in direct contact with or separated from but positioned above the semiconductor substrate. An entire surface of the low dielectric layer is subjected to a plasma treatment. Then, an opening exposing a predetermined region of the semiconductor substrate is formed by patterning the treated low dielectric layer. Finally, the opening is filled by a conductive layer.

The low dielectric layer is made of HSQ, and the plasma treatment employs one of the following gases: NH₃, N₂O, N₂, O₂, He, or Ar.

Further, after the conductive layer is formed, the conductive layer is etched for planarization to expose the low dielectric layer, or it is patterned by photo etching.

According to another embodiment of this invention a second method of forming an interconnection line is provided. The method begins by sequentially forming a first low dielectric layer and an etch stop layer on a semiconductor substrate where a first metal interconnection line has already been formed. A first opening exposing a predetermined portion of the first dielectric layer is formed by patterning the etch stop layer. A second low dielectric layer is formed on the substrate after forming the first opening therein, and an entire surface of the second low dielectric layer is subjected to plasma treatment. A second opening exposing a predetermined portion of the first metal interconnection line is formed by sequentially patterning the second and first low dielectric layers. A conductive layer filling the second opening is formed on the first and second low dielectric layers.

The present invention will be better understood from the following detailed description of the exemplary embodiment thereof taken in conjunction with the accompanying drawings, and its scope will be pointed out in the appended claims.

### BRIEF DESCRIPTION OF THE DRAWINGS

The present invention will be described by way of exemplary embodiments, but not limitations, illustrated in the accompanying drawings in which like references denote similar elements, and in which:

FIG. 1a through FIG. 1j are cross sectional views showing the sequence of process steps for an interconnection line according to a preferred embodiment of the present invention; and

FIG. 2 is a scanning electron microscopy (SEM) picture showing a copper interconnection line according to a preferred embodiment of the present invention.

### DETAILED DESCRIPTION

The following detailed description discloses the best modes presently contemplated by the inventors for practicing the invention. It should be understood that the description of these preferred embodiments is merely illustrative and that they should not be taken in a limiting sense.

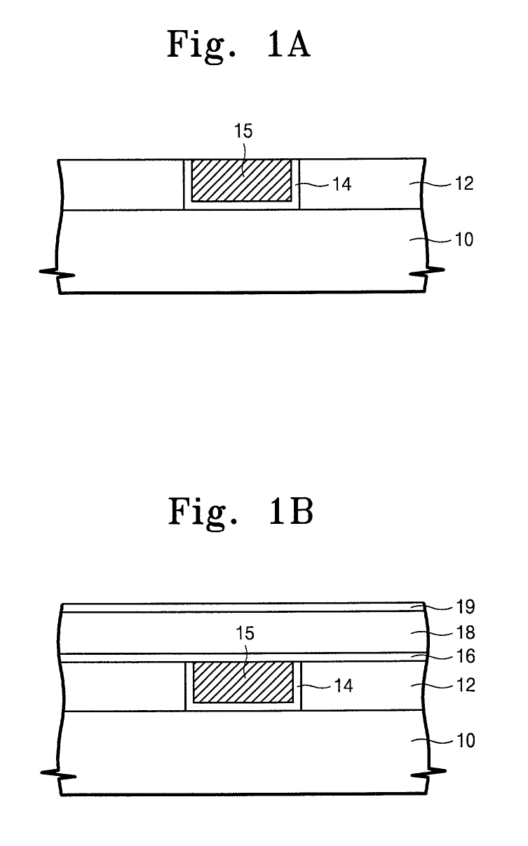

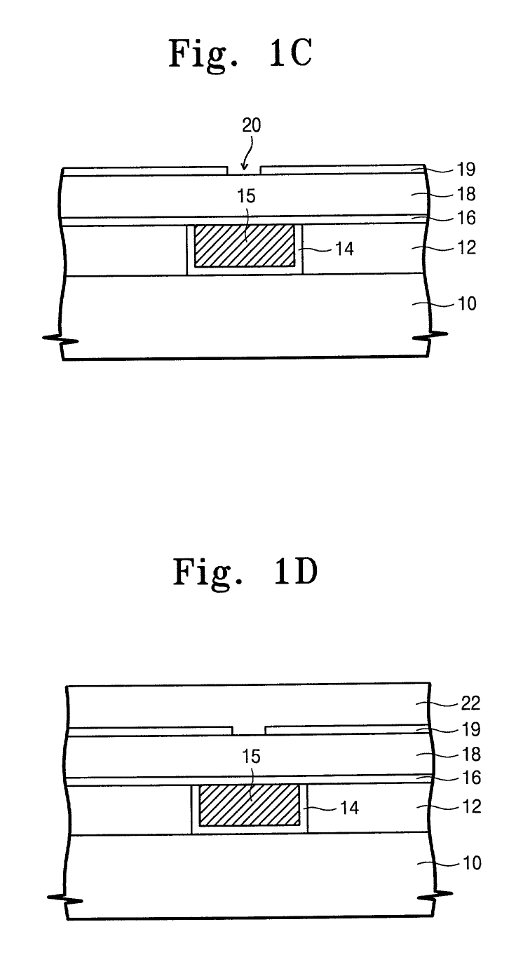

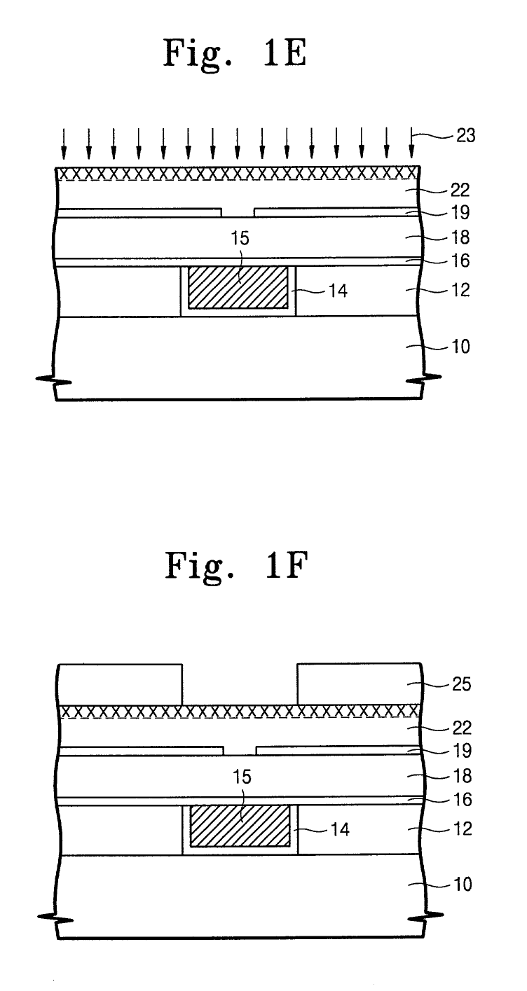

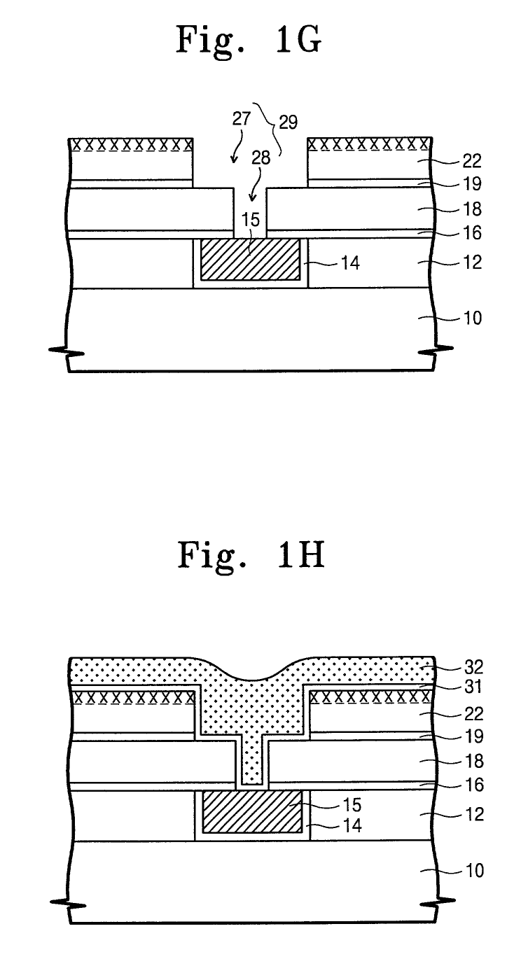

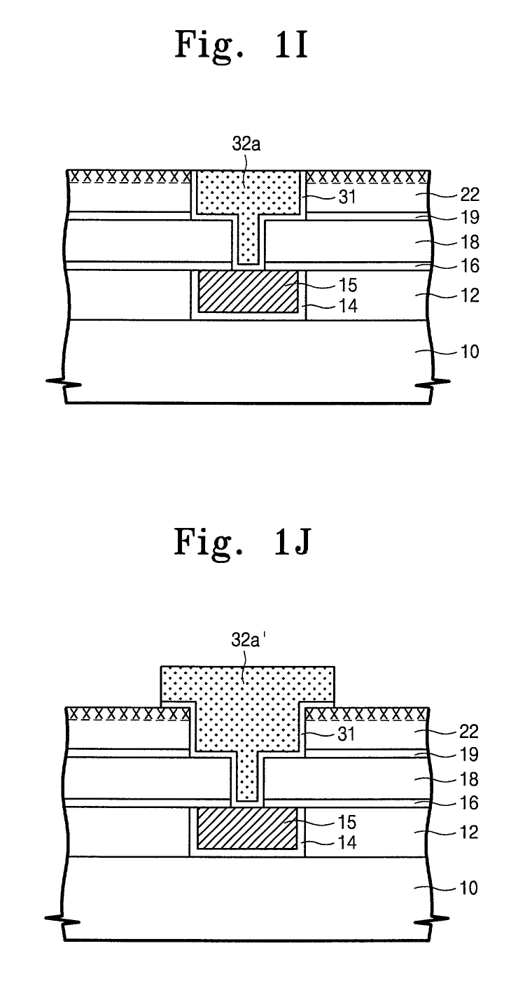

FIG. 1a through FIG. 1j are cross sectional views showing the sequence of processing steps for an interconnection line according to a preferred embodiment of the present invention.

Referring to FIG. 1a, an insulating layer 12 and a first metal interconnection line 15 are formed over a semiconductor substrate 10. The first metal interconnection line 15 is formed within the insulating layer 12. It is preferable that a barrier layer 14 is formed between the insulating layer 12 and the first metal interconnection line 15. The first metal interconnection line 15 is formed by conventional manufacturing processes such as the damascene process.

Referring to FIG. 1b, a capping layer 16 is formed over the insulating layer 12 having the first metal interconnection line 15. If the first metal interconnection line 15 is made of copper (Cu), the capping layer 16 not only prevents copper from being diffused into the insulating layer 12 enclosing the metal line 15 but also is used as an etch stop layer in a subsequent etch process. The capping layer 16 is made of silicon nitride formed by chemical vapor deposition (CVD).

A first low dielectric layer 18 made of hydrosilsesquioxane (HSQ) is formed on the capping layer 16 to insulate the first metal interconnection line 15. The first HSQ layer 18 is formed by the spin-on coating technique, and has a thickness of 2000 through 20000 Å. Then, the first HSQ layer 18 is subject to an annealing process. The annealing process includes a soft-bake process and a curing process. The soft-bake process is a low temperature thermal treatment to stabilize the HSQ layer 18, and the curing process is a high temperature thermal treatment to transform the HSQ layer into a silicon oxide layer. The soft-bake process includes a solvent evaporation step between temperatures of 100 and 200° C., a planarization step at temperatures between 150 and 250° C., and a stabilization step at temperatures between 250 and 350° C. The curing process occurs at a temperature of about 400° C., in a nitrogen or inert gas atmosphere and in a vacuum state of several torr.

An etch stop layer 19 of a different etch selectivity than the first insulating layer 18 is made of silicon oxide formed on the HSQ layer 18 using CVD after the curing process.

Referring to FIG. 1c, a photoresist layer (not shown) is formed over the etch stop layer 19. A photoresist pattern is formed by patterning the photoresist layer using a mask. A first opening 20 that exposes a predetermined portion of the fist insulating layer 18 is formed by etching the etch stop layer 19 using the photoresist pattern. The photoresist pattern is then removed.

Referring to FIG. 1d, a second insulating layer 22 made of HSQ is formed over etch stop layer 19 and fills the first opening 20. The second HSQ layer 22 is formed with an approximate thickness of 2000 through 20000 Å by a spin-on coating technique, then the soft-bake and curing processes proceed as described above.

Referring to FIG. 1e, a plasma treatment is performed to prevent damage of the second HSQ layer 22 by the developer used in the photo etching process for patterning the second HSQ layer 22. The processing gas for the plasma comprises at least one gas selected from the group consisting of NH₃, N₂O, N₂, O₂, He, and Ar. Further, the plasma is formed by an applied radio frequency (RF) power between 100 and 1000 W after the processing gas is injected into a reactor.

Due to the plasma treatment, the bond density of the HSQ layer 22 increases. Specifically, the HSQ layer 22 of (HSiO_{3/2})ₙ consists of Si—H, Si—OH, and Si—O bonds. When the HSQ layer 22 is subjected to the plasma treatment, the plasma becomes an energy source enhancing an oxidation reaction in the HSQ 22 layer, and reacts the HSQ layer 22 with a reactive ion and a radical therein. The initial cage structure of Si—H, Si—OH, and Si—O bonds is transformed into a network structure of Si—O—Si bonds, which is similar to that of silicon oxide. Or, if the plasma contains a reactive gas of nitrogen, the bond structure of the HSQ layer 22 becomes Si—N—O bonds after reaction with the nitrogen.

The upper layer bond density of HSQ layer 22 is increased by the reaction with the plasma, while the lower layer bond density of HSQ layer 22 retains the specific characteristics of the HSQ material without influence from the plasma. Consequently, the upper part of HSQ layer 22 has a higher density relative to the lower part of HSQ layer 22, thereby protecting the lower part of HSQ layer 22 from cracking.

Referring to FIG. 1f, a photoresist layer is formed on an entire plasma-treated surface of the second low dielectric layer 22. A photoresist pattern 25, exposing a predetermined region of the second dielectric layer 22, is formed by patterning the photoresist layer using a mask for the second metal interconnection line. Here, the second dielectric layer 22 will not crack when exposed to developer in the patterning step. The top surface of layer 22 is protected from cracking by the increased bond density resulting from plasma treatment 23.

Referring to FIG. 1g, the second and first dielectric layers 22 and 18 are sequentially dry etched using photoresist pattern 25. As a result, a hole 28 exposing a predetermined portion of capping layer 16, and a groove 27 having a broader width than hole 28 are simultaneously formed. Thereafter, a predetermined region of the first metal interconnection line 15 is exposed by removing the exposed capping layer 16 and etch stop layer 19 after photoresist pattern 25 is removed. Photoresist pattern 25 may also be removed after exposed capping layer 16 and etch stop layer 19. Hole 28 and groove 27 together form a second opening 29.

Referring to FIG. 1h, a barrier layer 31 is conformally formed over the substrate after forming second opening 29. If a metal interconnection line is made of copper, the barrier layer 31 prevents copper from being diffused into the second and first low dielectric layers 22 and 18 enclosing the metal interconnection line. The barrier layer 31 includes at least a layer made of Ti, TiN, WN, Ta, or TaN. A conductive layer 32 for a second metal interconnection line, filling the second opening 29, is formed on the barrier layer 31. The conductive layer 32 is made of either copper (Cu), aluminum (Al) or tungsten (W).

Referring to FIG. 1i, a second metal interconnection line 32a is formed by etching the conductive layer 32 and barrier layer 31 for planarization until a top surface of the second low dielectric layer 22 is disclosed. Here, the conductive layer 32 and the barrier layer 31 are etched for planarization by chemical mechanical polishing (CMP) or etch-back.

Referring to FIG. 1j, a second metal interconnection line 32a′ may be formed by patterning the conductive layer 32 using the conventional photo etching process.

In this manner, as the low dielectric layer composed of HSQ is subjected to the plasma treatment, the bond density of the upper level of the HSQ layer increases. Thus, the HSQ layer can be patterned directly with the photo etching process without first forming a hard mask upon it.

Refractive index variation of the HSQ layer is shown in the following table to verify variation of the HSQ layer after the plasma treatment. First, the HSQ layer is formed with a thickness between 3700 and 3900 Å on a semiconductor substrate, and is subjected to the plasma treatment using a gas such as NH₃, N₂O, N₂, or O₂. The plasma treatment is progressed using plasma enhanced CVD (PE-CVD) apparatus, and the plasma is formed by receiving the radio frequency (RF) power of 100 through 1000 W in a pressure of 5 torr. The processing time for the plasma treatment is about one minute.

TABLE

| | | Transformed Upper | | Untransformed Lower | |
|---|---|---|---|---|---|
| | | Layer after the | | Layer after the | |
| | Thickness of | Plasma Treatment | | Plasma Treatment | |
| | Layer | Thickness | Refractive | Thickness | Refractive |
| Gas | (Å) | (Å) | Index | (Å) | Index |
| NH₃ | 3762 | 270 | 1.58 | 3492 | 1.37 |
| N₂ | 3846 | 107 | 1.63 | 3739 | 1.38 |
| N₂O | 3849 | 294 | 1.46 | 3555 | 1.37 |
| O₂ | 3744 | 573 | 1.51 | 3171 | 1.38 |

As shown in above table, the refractive index of the upper layer of the HSQ layer is increased after the plasma treatment. To be concrete, the refractive index of the plasma-treated upper layer rises up to 1.46 or 1.58, which is similar in value to a silicon-rich oxide (Si-rich SiO₂) layer. Consequently, if the HSQ layer is subjected to the plasma treatment, the upper layer of the HSQ layer is transformed into Si-rich SiO₂ layer by oxidation reaction. The lower layer of the HSQ layer that was unexposed to the plasma retains the specific refractive index of HSQ.

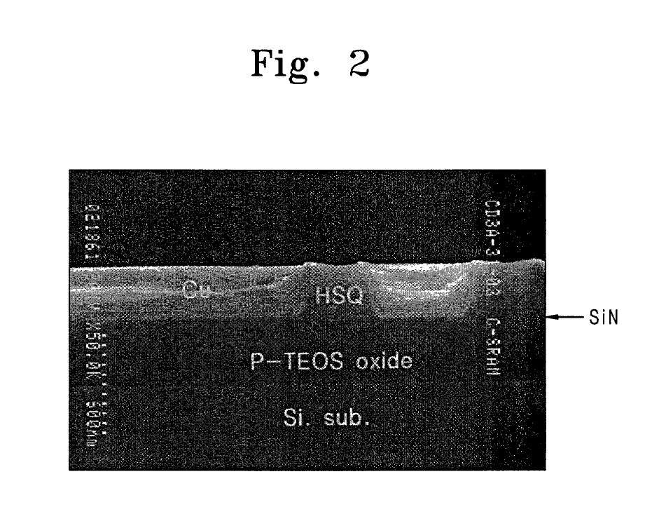

FIG. 2 is a scanning electron microscopy (SEM) picture showing a copper interconnection line formed by the preferred embodiment of the present invention. A lower insulating layer made of plasma-enhanced tetraethylorthosilicate (PE-TEOS) and an etch stop layer made of silicon nitride are sequentially formed on a semiconductor substrate. The PE-TEOS layer is formed with a thickness of 4200 Å by CVD technique employing TEOS, and the silicon nitride layer is formed with a thickness of 500 Å by CVD technique employing SiH₄ and NH₃. The HSQ layer is formed with a thickness 3700 Å on the silicon nitride layer, and then treated in plasma employing NH₃. An opening is formed by patterning the plasma-treated HSQ layer with a photoetching process. A barrier layer made of TaN is formed in the opening with a thickness 450 Å. After that, the opening is filled with Cu, and a Cu interconnection line of damascene structure is formed by chemical-mechanical polishing (CMP) process.

As shown in FIG. 2, the Cu interconnection line formed by the preferred embodiment of the invention has an improved profile, which shows an effect of the plasma treatment. In other words, the plasma treatment of the HSQ layer prevents damage to the HSQ layer during the photo etching process, so that interconnection lines with excellent profiles are formed.

According to the present invention, the HSQ layer can be patterned directly after performing the plasma treatment on the HSQ layer, which prevents damage to the HSQ layer during the photoetching process. Hence, the HSQ layer can be patterned without using a hard mask, and the process of forming the interconnection line is simplified by using the HSQ layer as the interlayer insulating layer.

Further, as the HSQ layer is the low dielectric layer, the parasitic capacitance therein is decreased to improve the resistance-capacitance (RC) delay.

While the invention has been described in terms of an exemplary embodiment, it is contemplated that it may be practiced as outlined above with modifications within the spirit and scope of the appended claims.

1. A method for forming interconnection lines, comprising the steps of:
forming a low dielectric layer over a semiconductor substrate;
performing a plasma treatment on a surface of the low dielectric layer thereby resulting in a plasma-treated surface;
forming an opening through a predetermined portion of the low dielectric layer having the plasma-treated surface; and
forming a conductive layer filling the opening.

2. The method of claim 1, wherein the low dielectric layer is made of hydrosilsesquioxane (HSQ).

3. The method of claim 1, wherein the plasma treatment employs at least one gas selected from the group consisting of NH₃, N₂O, N₂, O₂, He, and Ar.

4. The method of claim 1, the method further comprising a step of etching the conductive layer for planarization to expose the low dielectric layer after the step of forming the conductive layer.

5. The method of claim 1, the method further comprising a step of forming an interconnection line covering the opening by patterning the conductive layer with a photo etching process after the step of forming the conductive layer.

6. The method of claim 1, wherein the conductive layer is made of an element from the group consisting of aluminum (Al), tungsten (W) and copper (Cu).

7. The method of claim 1, wherein the method of forming the opening comprises the steps of:
forming a photoresist layer over the low dielectric layer;
forming a photoresist pattern exposing a predetermined portion of the low dielectric layer by patterning the photoresist layer; and
etching the exposed low dielectric layer using the photoresist pattern.

8. The method of claim 1, the method further comprising a step of forming a barrier layer over an inner wall of the opening before the step of forming the conductive layer.

9. The method of claim 8, wherein the barrier layer includes a layer made of at least one selected from the group consisting of Ti, TiN, WN, Ta, and TaN.

10. A method of forming interconnection lines, comprising the steps of:
forming a first low dielectric layer over a semiconductor substrate where a first metal interconnection line is formed therein;
forming an etch stop layer over the first low dielectric layer;
forming a first opening exposing a predetermined portion of the first dielectric layer by patterning the etch stop layer;
forming a second low dielectric layer over the substrate after forming the first opening;
performing a plasma treatment on a surface of the second low dielectric layer, thereby resulting in a plasma-treated surface;
forming a second opening that exposes a predetermined portion of the first metal interconnection line by sequentially patterning the plasma-treated second low dielectric layer and the first low dielectric layer; and
forming a conductive layer filling the second opening.

11. The method of claim 10, wherein the first and second low dielectric layers are made of hydrosilsesquioxane (HSQ).

12. The method of claim 11, wherein the HSQ layer is formed by using a spin-on coating technique, said layer having a thickness of approximately 2000 through 20000 Å.

13. The method of claim 10, wherein the conductive layer is made of an element from the group consisting of Al, W, and Cu.

14. The method of claim 10, wherein the etch stop layer is made of silicon nitride.

15. The method of claim 10, the method further comprising a step of forming a barrier layer over an inner wall of the opening before the step of forming the conductive layer.

16. The method of claim 15, wherein the barrier layer includes a layer made of at least one selected from the group consisting of Ti, TiN, WN, Ta, and TaN.
